(19) United States
(12) Patent Application Publication
(10) Pub. No.: US 2025/0196258 A1
(43) Pub. Date: Jun. 19, 2025

(54) LASER PROCESSING EQUIPMENT AND LASER PROCESSING METHOD

(71) Applicant: PlayNitride Display Co., Ltd., MiaoLi County (TW)

(72) Inventors: Yen-Mu Chen, MiaoLi County (TW); Chih-Chien Tung, MiaoLi County (TW)

(73) Assignee: PlayNitride Display Co., Ltd., MiaoLi County (TW)

(21) Appl. No.: 18/544,437

(22) Filed: Dec. 19, 2023

(51) Int. Cl. B23K 26/066; B23K 26/0622; B23K 26/067; G02B 26/08

(52) U.S. Cl. CPC B23K 26/066; B23K 26/0622; B23K 26/0676; G02B 26/0816

(57) ABSTRACT

A laser processing equipment includes a laser unit and a carrier. The laser unit includes a pulsed laser light source, a vibration mirror, a mask, and a focusing module. The pulsed laser light source provides a pulsed laser beam. The vibration mirror turns the pulsed laser beam. The mask receives the pulsed laser beam. The mask has multiple openings distributed along a first direction. The openings are used to allow the pulsed laser beam to pass through. The focusing module respectively focuses the pulsed laser beam passing through the openings into multiple laser spots distributed along the first direction. The carrier carries multiple processing elements. The processing elements are disposed corresponding to distribution positions of the laser spots along the first direction. A laser processing method is also provided.

### BACKGROUND

### Technical Field

The disclosure relates to a laser processing equipment and a laser processing method.

### Description of Related Art

The micro light-emitting diode (micro LED) may be transferred to a backplane through a laser transfer technology, but generally speaking, the crystallite side length of the micro LED unit is less than 100 microns, or even less than 50 microns. With the current laser transfer technology, whether using high energy (for example, the development of excimer laser or high-energy diode-pumped solid-state laser) or high pulse-repetition-rate diode-pumped solid-state laser, issues with space or time energy usage efficiency may occur. In addition, the high repetition rate laser may also have temporal jitter due to synchronization issues with the scanner, causing spatial accuracy issues.

### SUMMARY

The disclosure provides a laser processing equipment that can have high accuracy and high energy usage efficiency, and can achieve high production capacity.

The disclosure provides a laser processing method that can achieve high accuracy, high energy usage efficiency, and high production capacity.

An embodiment of the disclosure provides a laser processing equipment, including a laser unit and a carrier. The laser unit includes a pulsed laser light source, a vibration mirror, a mask, and a focusing module. The pulsed laser light source is used to provide a pulsed laser beam. The vibration mirror is used to turn the pulsed laser beam. The mask is used to receive the pulsed laser beam. The mask has multiple openings distributed along a first direction. The openings are used to allow the pulsed laser beam to pass through. The focusing module is used to respectively focus the pulsed laser beam passing through the openings into multiple laser spots distributed along the first direction. The carrier is used to carry multiple processing elements. The processing elements are disposed corresponding to distribution positions of the laser spots along the first direction.

An embodiment of the disclosure provides a laser processing method, including providing a first substrate including a processing element array, irradiating processing elements in a first row in the processing element array on the first substrate with laser spots extending in a first direction, separating the processing elements in the first row from the first substrate, transferring the processing elements in the first row to a second substrate, irradiating processing elements in a non-adjacent second row in the processing element array on the first substrate with the laser spots extending in the first direction, separating the processing elements in the second row from the first substrate and transferring the processing elements in the second row to the second substrate to form an relay processing element array, rotating the second substrate 90 degrees according to a normal direction, turning the second substrate upside down, irradiating processing elements in a first column in the relay processing element array on the second substrate with the laser spots extending in the first direction, irradiating processing elements in a non-adjacent second column in the relay processing element array on the second substrate with the laser spots extending in the first direction, separating the processing elements in the second column from the second substrate, and transferring the processing elements in the second column to a third substrate.

Based on the above, in the laser processing equipment and the method thereof according to the embodiments of the disclosure, the laser processing equipment includes the laser unit and the carrier. The laser unit includes the pulsed laser light source, the vibration mirror, the mask, and the focusing module. The pulsed laser light source provides the pulsed laser beam. The vibration mirror turns the pulsed laser beam. The mask receives the pulsed laser beam. The mask has the openings distributed along the first direction. The openings are used to allow the pulsed laser beam to pass through. The focusing module is used to respectively focus the pulsed laser beam passing through the openings into the laser spots distributed along the first direction. The carrier carries the processing elements. In addition, the processing elements are disposed corresponding to the distribution positions of the laser spots along the first direction. In this way, the accuracy can be improved, the high energy usage rate can be increased, and the high production capacity can be achieved.

### BRIEF DESCRIPTION OF THE DRAWINGS

FIG. 1 is a schematic diagram of a laser processing equipment according to an embodiment of the disclosure.

FIG. 2 is a schematic diagram of a laser processing equipment according to an embodiment of the disclosure.

FIGS. 3A to 3D are schematic top diagrams of a mask of a laser processing equipment according to an embodiment of the disclosure.

FIG. 4 is a schematic diagram of a laser processing equipment according to an embodiment of the disclosure.

FIG. 5 is a schematic diagram of a substrate of a laser processing equipment according to an embodiment of the disclosure.

FIG. 6 is a schematic diagram of a laser processing equipment according to an embodiment of the disclosure.

FIG. 7 is a schematic top diagram of the substrate of the laser processing method according to FIG. 5.

### DESCRIPTION OF THE EMBODIMENTS

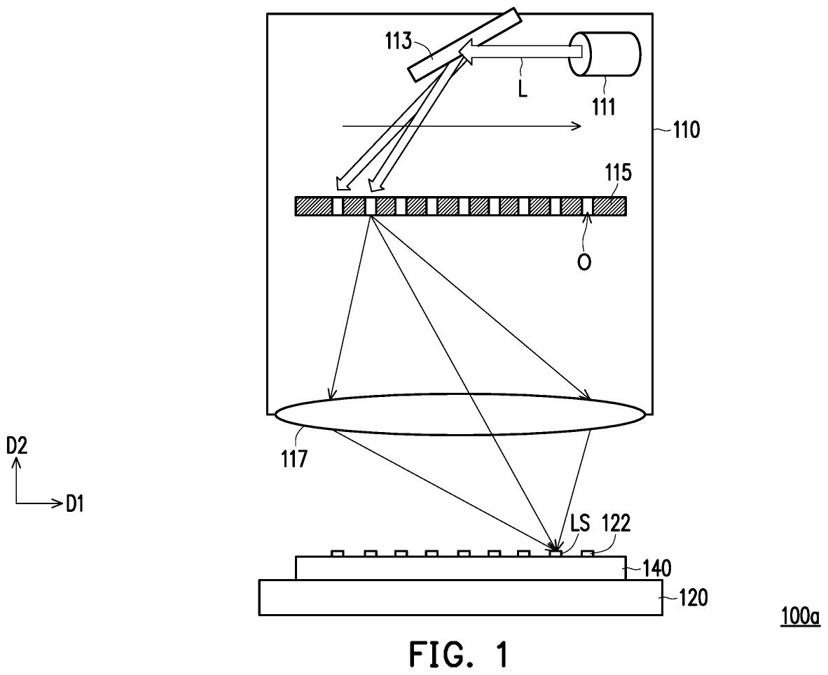

FIG. 1 is a schematic diagram of a laser processing equipment according to an embodiment of the disclosure. A laser processing equipment 100 includes a laser unit 110 and a carrier 120. The laser unit 110 includes a pulsed laser light source 111, a vibration mirror 113, a mask 115, and a focusing module 117. The pulsed laser light source 111 is used to provide a pulsed laser beam L. The vibration mirror 113 is used to turn the pulsed laser beam L, and the mask 115 is used to receive the pulsed laser beam L.

The mask 115 has multiple openings O distributed along a first direction D1. The pulsed laser beam L, which is slightly larger than the opening O, sequentially scans the openings along the first direction D1. When the pulsed laser beam L passes through the opening O, each of the openings O sequentially lights up.

The opening O is used to allow the pulsed laser beam L to pass through. The focusing module 117 is used to respectively focus the pulsed laser beam L passing through the openings O into multiple laser spots LS distributed along the first direction D1.

The carrier 120 is used to carry multiple processing elements 122 on a substrate (such as a first substrate 140). The processing elements 122 are disposed corresponding to distribution positions of the laser spots LS along the first direction D1.

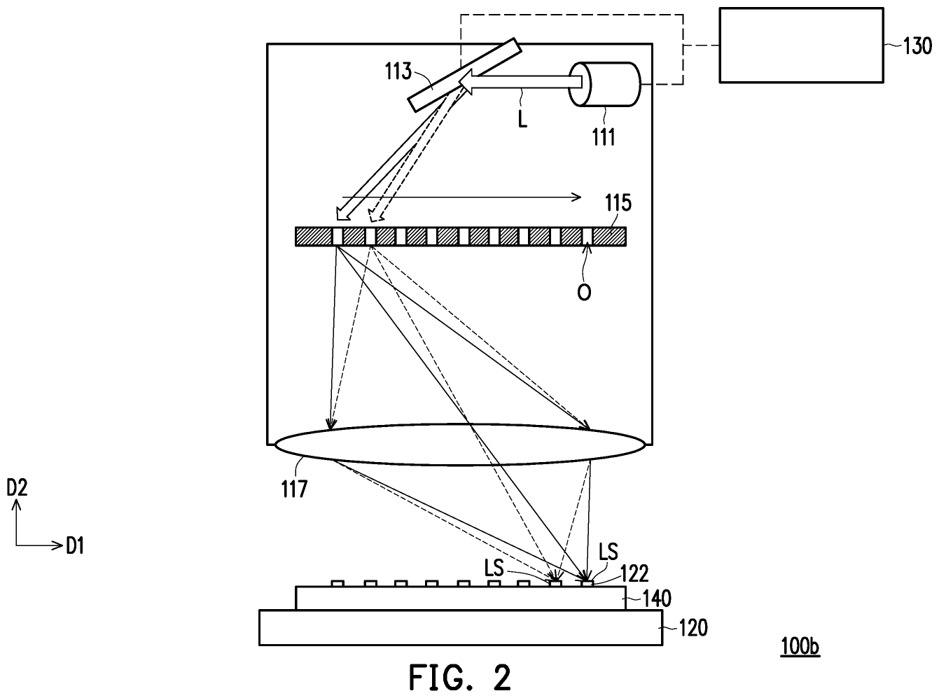

FIG. 2 is a schematic diagram of a laser processing equipment according to an embodiment of the disclosure. The laser processing equipment 100 further includes a control unit 130. The control unit 130 controls a continuous rotation of the vibration mirror 113.

The pulsed laser light source 111 operates in a pulse on demand (POD) mode. The pulse on demand mode may be triggered according to an external signal. The control unit 130 may send the external signal to the pulsed laser light source 111 according to an achievement of a specific condition, so that the pulsed laser light source 111 emits the pulsed laser beam L at a specific time point.

The specific condition here means that when the vibration mirror 113 is continuously rotating (at a constant velocity, a constant angular velocity, or a fixed angular acceleration), the pulsed laser beam L from the pulsed laser light source 111 may be reflected to the direction of the specific opening O, and the pulsed laser light source 111 is triggered only then. The pulsed laser beam L may be irradiated to the specific opening O.

In contrast, repetitive pulses with a fixed frequency require an additional acousto-optic modulator to be filtered. Only when an angle of the vibration mirror meets the above state may a certain pulse be emitted (the pulse is otherwise filtered out, which wastes power).

In other words, when the angle of the vibration mirror meets the above state, a certain pulse among the repetitive pulses may not be exactly about to be emitted, causing the vibration mirror to stop, then start to rotate again (that is, to provide the angular acceleration again) to the next position after the laser pulse is emitted, and stop rotating (that is, to provide a negative angular acceleration). Therefore, the pulsed laser light source 111 of the disclosure uses the pulse on demand (PoD) mode, so that the vibration mirror 113 does not need to stop, fire, and rotate. In this way, the time required for processing can be shortened.

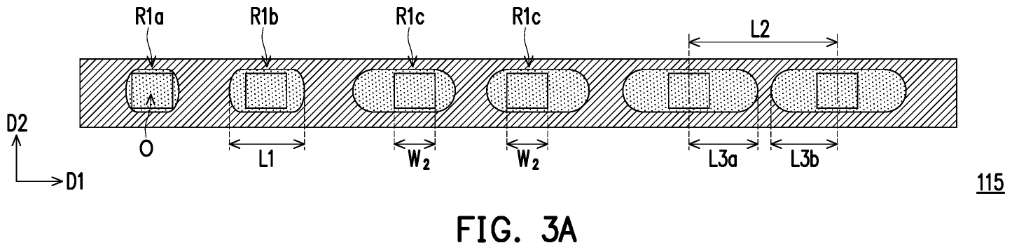

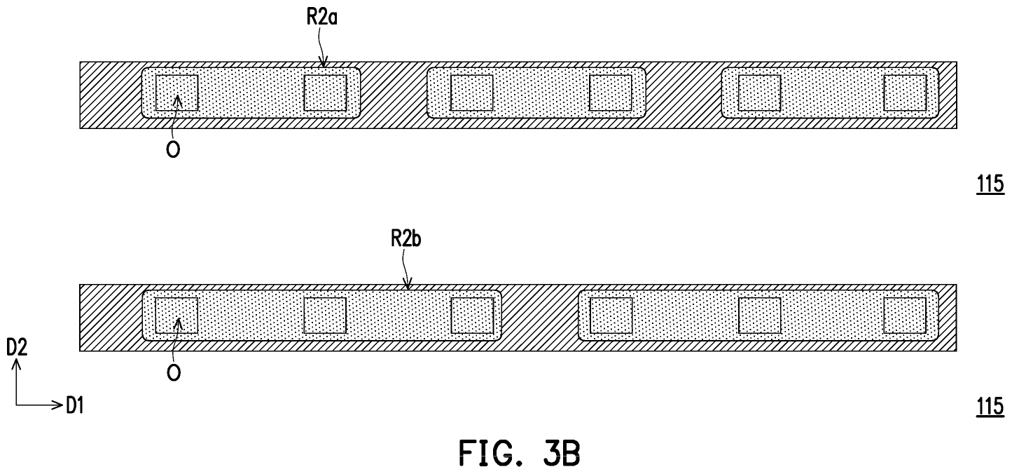

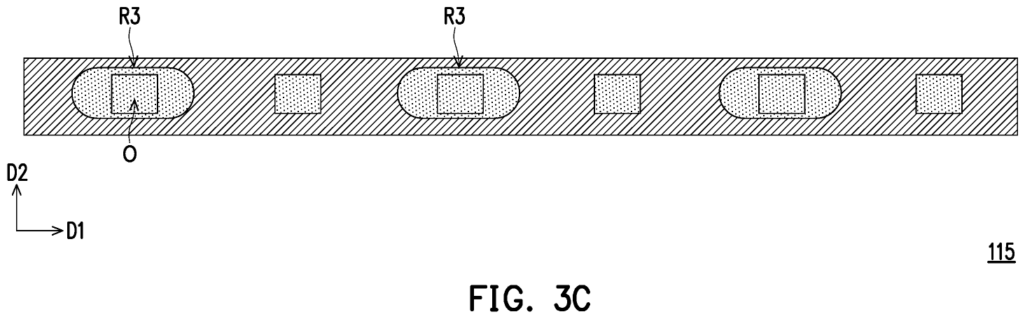

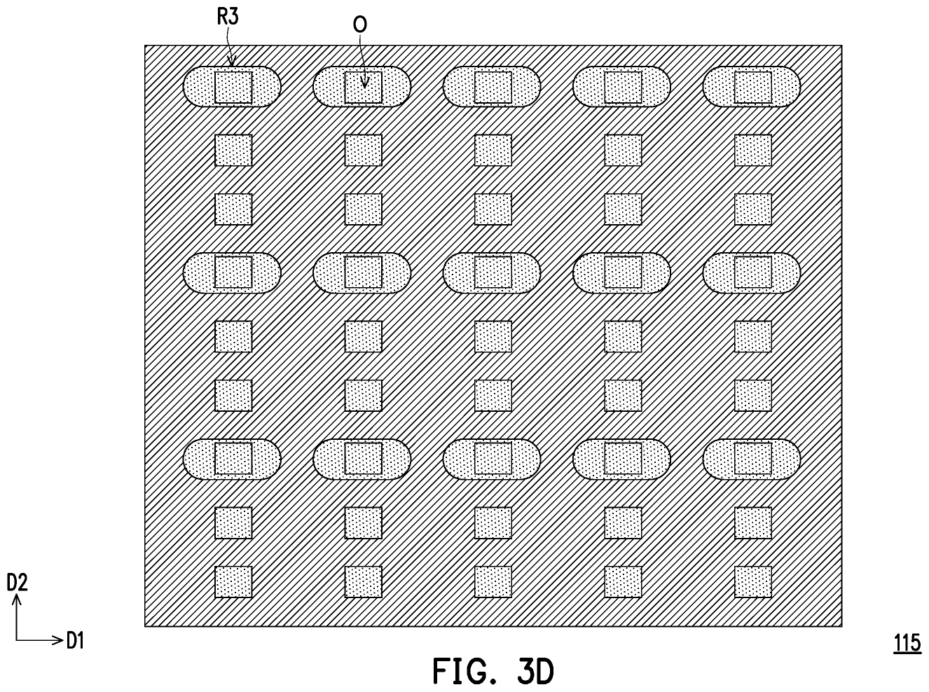

In this embodiment, when the pulsed laser light source 111 is in the pulse on demand mode, the control unit 130 drives the pulsed laser light source 111. When a projection range of the pulsed laser beam L is aligned with the openings O, the pulsed laser light source 111 emits the pulsed laser beam L. The projection range of the pulsed laser beam L may be aligned with the openings O, including an example as shown in FIGS. 3A to 3D, where an irradiation range of the pulsed laser beam L covers the openings O.

FIGS. 3A to 3C are schematic top diagrams of a mask of a laser processing equipment according to an embodiment of the disclosure.

As shown in FIG. 3A, the vibration mirror 113 turns the pulsed laser beam L, so that an irradiation range R1a of the pulsed laser beam L covers at least one opening O. The irradiation range R1a is required to completely cover the opening O on the mask 115. That is, the irradiation range R1a completely covers, rather than just covering part of, the opening O, to ensure that the pulsed laser beam L passing through the opening O may completely present a shape of the opening O without defects, thereby improving an accuracy and a yield when the focused laser spot LS is irradiated on the processing element 122.

When the vibration mirror 113 continuously rotates, the pulsed laser beam L forms an elongated irradiation range R1b on the mask 115. A length L1 of the elongated irradiation range R1b is less than twice a width W2 of the opening, thereby reducing a laser energy of the pulsed laser beam L being blocked and wasted.

In addition, in an embodiment, an elongated irradiation range R1c may be asymmetrical relative to the opening O, which can accept a greater triggering time point error. A sum of lengths (that is, the sum of L3a and L3b) of the irradiation range of the laser beam between two adjacent openings along the first direction D1 is less than 90% of a pitch L2 between the two adjacent openings along the first direction D1. Compared with the pulsed laser light source 111 irradiated on the entire pitch between the two adjacent openings O, this technology reduces a proportion of ineffective areas in an irradiation pitch, thereby reducing a power consumption of the pulsed laser light source 111.

As shown in FIG. 3B, when the vibration mirror 113 turns the pulsed laser beam L, an irradiation range R2a of the pulsed laser beam L sequentially covers the adjacent openings O along the first direction D1. In this embodiment, each of the openings O has the equal pitch. For example, the irradiation range R2a of the pulsed laser beam L sequentially covers any two adjacent openings O or an irradiation range R2b of the pulsed laser beam L sequentially covers any three adjacent openings O along the first direction D1. Therefore, the difference between FIG. 3B and FIG. 3A mainly lies in the difference in the irradiation ranges.

As shown in FIG. 3C, when the vibration mirror 113 turns the pulsed laser beam L, an irradiation range R3 of the pulsed laser beam L sequentially covers the non-adjacent openings O.

In this way, in the first direction D1, even if the irradiation range generated by the continuous rotation of the vibration mirror 113 only completely covers the opening O, part of a pitch L2 between the openings O along the first direction D1 is still not irradiated by the pulsed laser beam L.

Therefore, the length L1 of the irradiation range of the pulsed laser beam L in the first direction D1 only needs to be greater than the width W2 of the opening O in the first direction D1 and does not need to be equal to or greater than the width of the pitch L2 between the openings O. When there is no processing element to be transferred, there is no redundant pulsed laser beam L irradiated on the mask, thereby effectively reducing energy waste.

As shown in FIG. 3D, when the mask has multiple groups of the openings O arranged along a second direction D2 and each group of the openings O has the openings O distributed along the first direction D1, since the irradiation range R3 of the pulsed laser beam L corresponding to each of the openings O on the mask only needs to be greater than the width of the opening and does not need to be equal to or greater than the width of the pitch between the openings, when there is no processing element to be transferred, there is no redundant pulsed laser beam irradiated on the mask, thereby effectively reducing the energy waste. The first direction D1 may be orthogonal to the second direction D2.

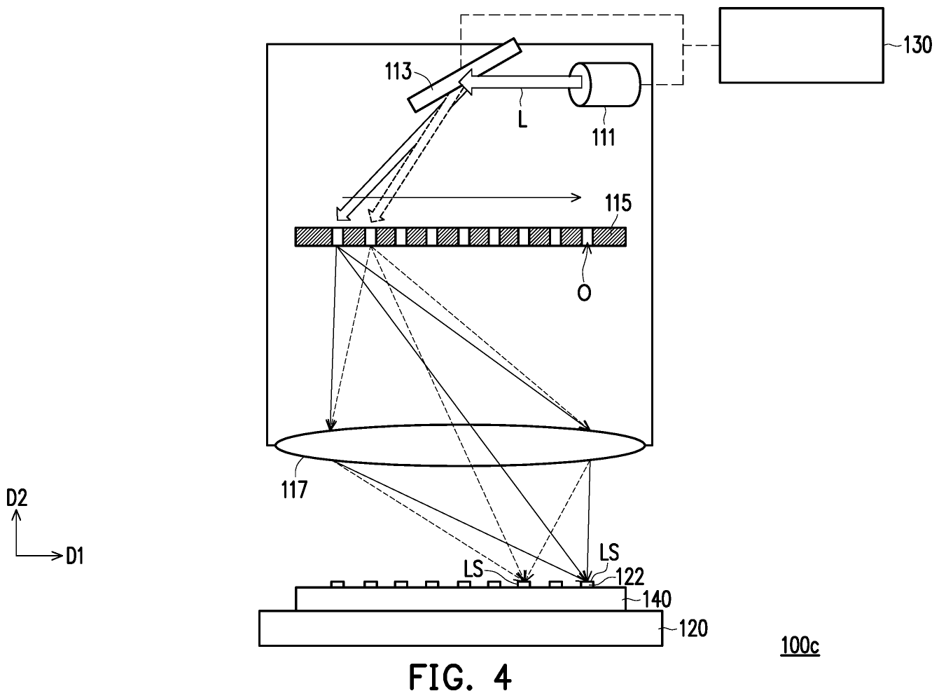

FIG. 4 is a schematic diagram of a laser processing equipment according to another embodiment of the disclosure. The difference between FIG. 4 and FIG. 2 is that the focusing module 117 respectively focuses the pulsed laser beam L passing through the openings O into the laser spots LS distributed along the first direction D1, and the adjacent laser spots LS are irradiated on the non-adjacent processing elements 122. In this way, the laser spots LS distributed along the first direction may be irradiated on the specific processing element 122, thereby effectively improving the usage efficiency of the pulsed laser light source 111 and increasing a mass production capacity.

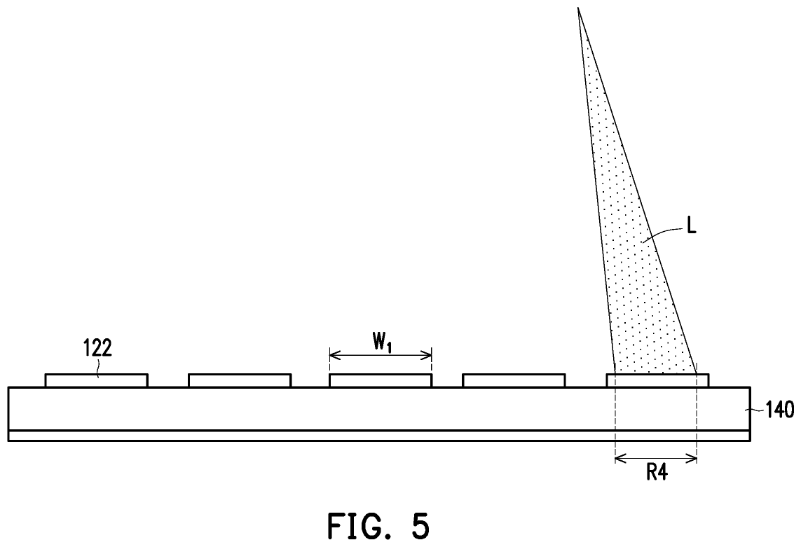

FIG. 5 shows a definition of the pulsed laser beam L passing through the opening O and a convergence of the focusing module 117. The width of an irradiation range R4 of the laser spots LS along the first direction D1 may be controlled to be less than a width W1 of the processing elements 122 along the first direction D1. In this way, a phenomenon of the pulsed laser beam L being irradiated on the substrate (such as the first substrate 140) can be reduced, and a processing uncertainty caused by the pulsed laser beam L being irradiated on the substrate (such as the first substrate 140) can be effectively reduced.

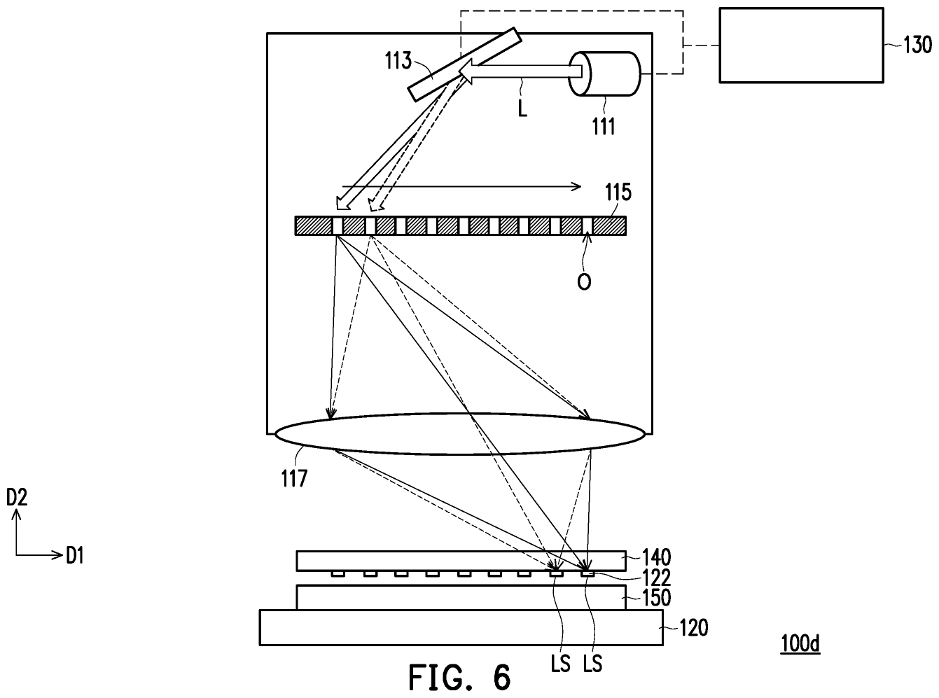

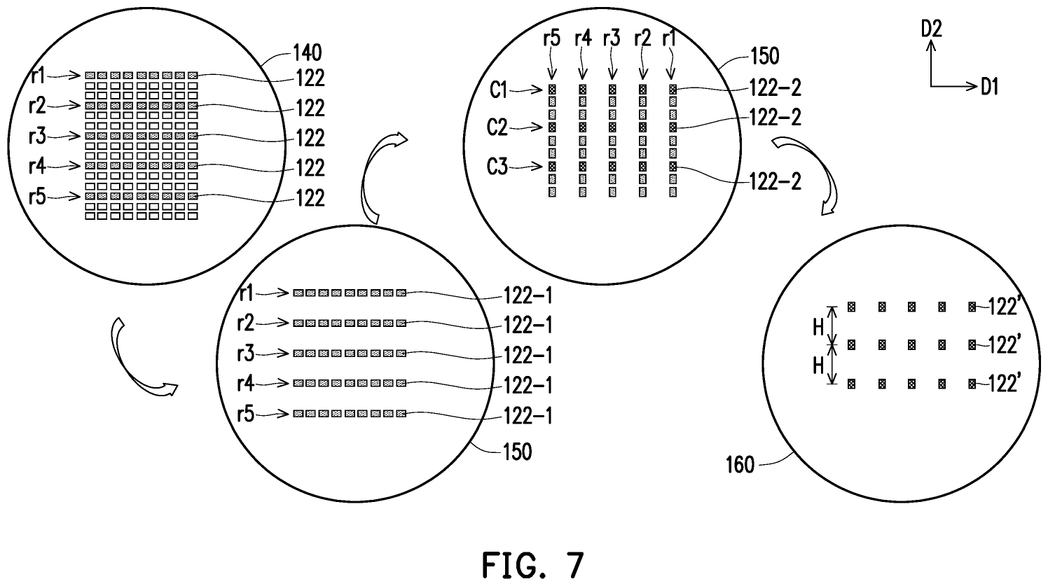

The embodiment of the disclosure provides a processing method. A laser processing method of the embodiment of the disclosure may be applied to the laser processing equipment in each of the above embodiments. The following takes a laser processing equipment 100d in FIG. 6 as an example. Please refer to FIG. 6 and FIG. 7.

As shown in FIGS. 6 and 7, the laser processing method of this embodiment includes the following steps. The first substrate 140 including an array of the processing elements 122 is provided. The processing elements 122 in a first row r1 in the array of the processing elements 122 on the first substrate 140 are irradiated by the laser spots LS extending in the first direction D1.

The processing elements 122 in the first row r1 are separated from the first substrate 140 and transferred to a second substrate 150. The processing elements 122 in a non-adjacent second row r2 in the array of the processing elements 122 on the first substrate 140 are irradiated by the laser spots LS extending in the first direction D1.

The processing elements 122 in the second row r2 are separated from the first substrate 140 and transferred to the second substrate 150 to form a relay processing element array. The same method is used for third to fifth rows (r3 to r5). Multiple relay processing elements 122-1 distributed along the first direction D1 may be obtained on the second substrate 150.

Compared with the distribution of the relay processing elements 122-1 along the second direction D2 on the first substrate 140, on the second substrate 150, there may be a greater pitch between each of the rows (r1 to r5) along the second direction D2, and the pitch between the relay processing elements 122-1 is smaller along the first direction D1.

The second substrate 150 is rotated 90 degrees according to a normal direction and turned upside down, so that each row on the second substrate 150 becomes a column. Multiple relay processing elements 122-2 in a first column C1 in the relay processing element array on the second substrate 150 are irradiated by the laser spots LS extending in the first direction D1.

Then, the continuous relay processing elements 122-2 in the new first column C1 along the first direction D1 are removed from the second substrate 150, so that the continuous relay processing elements 122-2 in the new first column C1 along the first direction D1 are transferred to a third substrate 160.

The relay processing elements 122-2 in a non-adjacent second column C2 in the relay processing element array on the second substrate 150 are irradiated by the laser spots LS extending in the first direction D1. The continuous relay processing elements 122-2 in another non-adjacent column C2 along the first direction D1 are removed from the second substrate 150, so that the continuous relay processing elements 122-2 in the non-adjacent second column C2 along the first direction D1 are transferred to the third substrate 160. The continuous relay processing elements in a third column C3 along the first direction D1 are transferred by using the same method. In this embodiment, the directions of the column and the row are orthogonal.

In this embodiment, the pulsed laser light source 111 is a pulse on demand beam, and the mask 115 is provided to receive the pulsed laser beam L. The mask 115 has the openings O distributed along the first direction D1. The openings O are used to allow the pulsed laser beam L to pass through. When the projection range of the pulse on demand beam is aligned with the opening O, the pulsed laser light source 111 emits the pulse on demand beam. The pulsed laser light source 111 emits the pulse on demand beam using laser lift-off to remove the processing element from the substrate 140.

On the third substrate 160, a chip arrangement (C1 to C3) formed by processing multiple continuous processing elements 122′ along the first direction D1 may be obtained. A pitch H between each row along the second direction D2 meets the pitch on a target substrate.

For other details of the laser processing method in this embodiment, please refer to the description of the laser processing equipment in the above embodiments, which will not be repeated here.

To sum up, in the laser processing equipment and the method thereof according to the embodiments of the disclosure, the pulsed laser light source provides the pulsed laser beam. The vibration mirror turns the pulsed laser beam. The mask receives the pulsed laser beam. The mask has the openings to allow the pulsed laser beam to pass through. The focusing module is used to respectively focus the pulsed laser beam passing through the openings into the laser spots. The processing elements on the carrier are disposed corresponding to the distribution positions of the laser spots. In this way, the accuracy can be improved, the high energy usage efficiency can be increased, and the high production capacity can be achieved.

What is claimed is:

1. A laser processing equipment, comprising:
a laser unit, comprising:
a pulsed laser light source, configured to provide a pulsed laser beam;
a vibration mirror, configured to turn the pulsed laser beam;
a mask, configured to receive the pulsed laser beam, wherein the mask has a plurality of openings distributed along a first direction, and the plurality of openings are configured to allow the pulsed laser beam to pass through; and
a focusing module, configured to respectively focus the pulsed laser beam passing through the plurality of openings into a plurality of laser spots distributed along the first direction; and
a carrier, configured to carry a plurality of processing elements, wherein the plurality of processing elements are disposed corresponding to distribution positions of the plurality of laser spots along the first direction.

2. The laser processing equipment according to claim 1, further comprising a control unit, wherein the control unit controls a continuous rotation of the vibration mirror, in a pulse on demand mode, the control unit drives the pulsed laser light source, and when a projection range of the pulsed laser beam is aligned with the plurality of openings, the pulsed laser light source emits the pulsed laser beam.

3. The laser processing equipment according to claim 1, wherein the vibration mirror turns the pulsed laser beam, so that a first irradiation range of the pulsed laser beam covers at least one of the plurality of openings.

4. The laser processing equipment according to claim 1, wherein the vibration mirror turns the pulsed laser beam, so that a second irradiation range of the pulsed laser beam sequentially covers the plurality of adjacent openings along the first direction.

5. The laser processing equipment according to claim 1, wherein the vibration mirror turns the pulsed laser beam, so that a third irradiation range of the pulsed laser beam sequentially covers the plurality of non-adjacent openings.

6. The laser processing equipment according to claim 1, wherein the vibration mirror continuously rotates, so that the pulsed laser beam forms an elongated fourth irradiation range on the mask.

7. The laser processing equipment according to claim 6, wherein a length of the fourth irradiation range is less than twice an opening width of the plurality of openings.

8. The laser processing equipment according to claim 6, wherein the fourth irradiation range is asymmetrical relative to the opening.

9. The laser processing equipment according to claim 1, wherein the plurality of laser spots correspondingly generated by the plurality of openings correspond to the plurality of sequentially non-adjacent processing elements.

10. The laser processing equipment according to claim 1, wherein the mask has a plurality of groups of openings arranged along a second direction, and each of the groups of openings has a plurality of openings distributed along the first direction.

11. A laser processing method, comprising:
providing a first substrate comprising a processing element array, and irradiating processing elements in a first row in the processing element array on the first substrate with laser spots extending in a first direction;
separating the processing elements in the first row from the first substrate, transferring the processing elements in the first row to a second substrate, and irradiating processing elements in a non-adjacent second row in the processing element array on the first substrate with the laser spots extending in the first direction;
separating the processing elements in the second row from the first substrate and transferring the processing elements in the second row to the second substrate to form a relay processing element array;
rotating the second substrate 90 degrees according to a normal direction, turning the second substrate upside down, irradiating processing elements in a first column in the relay processing element array on the second substrate with the laser spots extending in the first direction, and irradiating processing elements in a non-adjacent second column in the relay processing element array on the second substrate with the laser spots extending in the first direction; and
separating the processing elements in the second column from the second substrate and transferring the processing elements in the second column to a third substrate.

12. The laser processing method according to claim 11, wherein a pulsed laser light source of the laser spot is a pulse on demand beam, and a mask is provided to receive a pulsed laser beam, wherein the mask has a plurality of openings distributed along the first direction, the plurality of openings are configured to allow the pulsed laser beam to pass through, and when a projection range of the pulse on demand beam is aligned with the opening, the pulsed laser light source emits the pulse on demand beam.

13. The laser processing method according to claim 11, wherein directions of a column and a row are orthogonal.

14. The laser processing method according to claim 11, wherein when the laser spots extending in the first direction are irradiated on the first substrate, the adjacent laser spots are irradiated on positions of the non-adjacent processing elements in the first row or the first column.
